(19) United States
(12) Patent Application Publication
(10) Pub. No.: US 2026/0331945 A1
(43) Pub. Date: Oct. 22, 2026

(54) METHOD, APPARATUS, AND SYSTEM FOR PREDICTING PERFORMANCE DEGRADATION OF A DISTRIBUTION TRANSFORMER

(71) Applicant: UBICQUIA, INC., FORT LAUDERDALE, FL (US)

(72) Inventors: Jow H. Ortiz, Coral Springs, FL (US); Gustavo Dario Leizerovich, Aventura, FL (US); Samuel Leonard Holden, Montreal (CA)

(21) Appl. No.: 19/529,096

(22) Filed: Feb. 3, 2026

Related U.S. Application Data
(60) Provisional application No. 63/753,929, filed on Feb. 4, 2025.

(51) Int. Cl. H02J 13/12; G01R 19/02; G01R 19/10; G01R 19/165; G01R 31/62; H02J 13/10

(52) U.S. Cl. CPC H02J 13/12; G01R 19/02; G01R 19/10; G01R 19/16547; G01R 31/62; H02J 13/10

(57) ABSTRACT

A distribution transformer monitoring system includes a monitoring device and a processor. The monitoring device may be collocated with a distribution transformer and configured to (a) detect voltages at two or more secondary terminals of the distribution transformer and (b) generate data signals representative of the detected secondary terminal voltages. The processor is operable in accordance with stored operating instructions to: receive the data signals from the monitoring device; determine, from the data signals, a difference between a magnitude of a voltage at a first secondary terminal of the distribution transformer and a magnitude of a voltage at a second secondary terminal of the distribution transformer to produce a voltage magnitude difference; determine whether the difference is greater than a threshold; and determine that performance of the distribution transformer has degraded or is degrading when the difference is greater than the threshold (e.g., for a minimum period of time).

### CROSS-REFERENCE TO RELATED APPLICATIONS

The present application claims the benefit of and priority upon U.S. Provisional Patent Application No. 63/753,929, which was filed on Feb. 4, 2025, and is incorporated herein by this reference as if fully set forth herein.

### TECHNICAL FIELD

The present disclosure relates generally to distribution transformer monitoring and, more particularly but not exclusively, to methods, apparatus, and systems for predicting distribution transformer performance degradation based on voltage divergence at the secondary terminals of the transformer.

### BACKGROUND

Distribution transformers are parts of the power system infrastructure. The power system infrastructure includes power lines, transformers and other devices for power generation, power transmission, and power delivery. A power source generates power, which is transmitted along high voltage (HV) power lines for long distances. Typical voltages found on HV transmission lines range from 69 kilovolts (kV) to more than 800 kV. The power signals are stepped down to medium voltage (MV) power and then stepped down further to low voltage (LV) levels at distribution transformers. LV power lines typically carry power signals having voltages ranging from about 100 V to about 600 V to customer premises.

In the United States local distribution transformers typically feed anywhere from one to ten homes, depending upon the concentration of the customer premises in a particular area. A power distribution system for a given area may include many distribution transformers. Thus, the monitoring costs, replacement costs and maintenance costs for distribution transformers can be a significant factor in the cost of power distribution.

A number of factors can adversely affect the life and operation of a distribution transformer. Distribution transformer monitors are used to monitor certain parameters of distribution transformers in some power distribution systems but such monitors do not predict likely degradation of a distribution transformer's operating performance based on such parameters.

### SUMMARY

According to one or more embodiments of the present disclosure, a processor executes a method for predicting performance degradation of a distribution transformer in an electrical power distribution system. The processor may be located remotely from the distribution transformer (e.g., in a cloud environment) or in a distribution transformer monitoring device (DTM) collocated with the distribution transformer (e.g., positioned on, within, or proximate to the distribution transformer). According to one embodiment of such a method, the processor receives data signals representative of voltages at two or more secondary terminals of the distribution transformer (e.g., the two secondary terminals of a single-phase distribution transformer). The data signals may be representative of root mean square (RMS) voltages or peak voltages, as so desired, although use of RMS voltages is preferred. The processor determines, from the received data signals, a difference between the magnitudes of the voltages at the two secondary terminals to produce a voltage magnitude difference. The processor then determines whether the voltage magnitude difference (peak or RMS) is greater than a threshold and, when it is, further determines that the performance of the distribution transformer has degraded or is degrading. To mitigate the likelihood of false positives (e.g., due to varying loading on the secondary terminals or otherwise), the processor may continue to monitor the secondary terminal voltages and determine the voltage magnitude difference over a minimum period of time, such as 12 hours, 24 hours, etc., to confirm that transformer performance degradation has occurred or is in process.

According to one exemplary embodiment, the voltage difference threshold may be set to about 3% of the magnitude of the secondary terminal output voltage (e.g., about 3.6 V_{RMS} where the nominal output voltage of each secondary terminal is typically about 120 V_{RMS}). According to alternative embodiments, the voltage difference threshold may be set to any value in a range of about 2% to about 5% of the nominal magnitude of the voltage at either secondary terminal. Therefore, where the nominal output voltage of each secondary terminal is typically about 120V_{RMS}, the voltage difference threshold may be set to any value in a range of about 2.5 V_{RMS} to about 5.0 V_{RMS}.

After determining that distribution transformer performance has degraded or is degrading, the processor may communicate a notification to a utility owning or controlling the distribution transformer to inform that the performance of the distribution transformer has degraded or is degrading. Such notification may be communicated by email, text, or other conventional means, or may more preferably be communicated by adding an alert to an Internet-accessible dashboard used by the utility to manage infrastructure components of the utility's electrical distribution system. For example, a cloud-based asset monitoring and analytics platform, such as the UBIVU® platform offered as a service by Ubicquia, Inc. of Fort Lauderdale, Florida, U.S.A., may provide such alerts to its utility customers and may operate as the processor when the processor is located remotely from the distribution transformer being monitored.

In other exemplary embodiments, the voltages at the secondary terminals of the distribution transformer are sensed, monitored, or otherwise detected by a monitoring device, such as the UBIGRID® DTM+ available from Ubicquia, Inc. The detected voltages are converted into data signals (e.g., through use of high speed analog-to-digital converters) that represent such voltages, which data signals are then either processed by a processor within the monitoring device or packetized for communication to a remote processor. In some embodiments, the processor is located remotely from the monitoring device and the distribution transformer. In other embodiments, the processor is located remotely from the distribution transformer and resides in a cloud environment. In further embodiments, the processor forms part of a monitoring device collocated with the distribution transformer.

According to another exemplary embodiment of the present disclosure, a distribution transformer monitoring system includes a monitoring device and a processor. According to this embodiment, the monitoring device is collocated with a distribution transformer and configured to (i) detect voltages at two or more secondary terminals of the distribution transformer and (ii) generate data signals representative of the detected voltages. Additionally, the processor is operable in accordance with stored operating instructions (e.g., stored in non-transitory memory) to: receive the data signals from the monitoring device; determine, from the received data signals, a difference between magnitudes (either peak or, more preferably, RMS) of voltages at two of the distribution transformer's secondary terminals to produce a voltage magnitude difference; determine whether the voltage magnitude difference is greater than a threshold (either instantaneously or, more preferably, for at least a minimum period of time); and determine that performance of the distribution transformer has degraded or is likely degrading when the voltage magnitude difference is greater than the threshold. Where RMS voltages are used to determine the voltage magnitude difference or imbalance, the data signals generated by the monitoring device and received by the processor are representative of the RMS voltages at the two secondary terminals of the distribution transformer.

In some embodiments of the distribution transformer monitoring system, the processor is located remotely from the monitoring device and the distribution transformer, and the monitoring device communicates the data signals representative of the detected secondary terminal voltages over a wireless communication network. In such embodiments, the processor may reside in a cloud environment that is web or Internet accessible.

In some embodiments of the distribution transformer monitoring system, the threshold for the voltage magnitude difference is in a range of about 2% to about 5% of the magnitude of the nominal or other ordinary operating voltage of either distribution transformer secondary terminal. For example, where the magnitudes of the voltages at the distribution transformer's secondary terminals are nominally about 120 V_{RMS}, the threshold for the voltage magnitude difference may be in a range of about 2.5 V_{RMS} to about 5.0 V_{RMS}.

According to another exemplary embodiment of the present disclosure, a distribution transformer monitoring system includes a monitoring device and a processor. According to this embodiment, the monitoring device is collocated with a distribution transformer and configured to (i) detect voltages at two or more secondary terminals of the distribution transformer and (ii) generate data signals representative of the detected voltages. Additionally, the processor is operable in accordance with stored operating instructions (e.g., stored in non-transitory memory) to: receive the data signals from the monitoring device; determine, from the received data signals, a difference between magnitudes (either peak or, more preferably, RMS) of voltages at two of the distribution transformer's secondary terminals to produce a voltage magnitude difference; determine whether the voltage magnitude difference is greater than a threshold for at least a minimum period of time; and determine that performance of the distribution transformer has degraded or is degrading when the voltage magnitude difference is greater than the threshold for at least the minimum period of time. According to some embodiments, the minimum period of time is twenty-four (24) hours.

In some embodiments, a method for detecting at least a voltage deviation event associated with (e.g., within or proximate to) a distribution transformer, such as a pad-mounted (padmount) or aerial (pole-mounted) distribution transformer may include monitoring output data or one or more output signals (such as one or more secondary voltage or current signals or other distribution transformer parameters) and determining, by a processor operably coupled to the distribution transformer, whether the output data or output signal(s) substantially corresponds to one or more data signatures representing voltage divergence events between secondary line voltages (and/or other events) at or above a predetermined threshold indicative of a potential failure mode of the distribution transformer. The method may further include communicating, by the processor via a communication interface, an alert to a local or a remote computing device when the output data or output signal(s) substantially corresponds to one of the data signatures indicative of the possible failure.

In some embodiments, the method can determine whether the output data substantially corresponds to one of a plurality of data signatures by determining, by the processor, whether an divergence event or measurement measured from secondary line voltage outputs of one or more distribution transformers is greater than or equal to a voltage threshold which would be indicative of a malfunction of the one or more distribution transformers. In some embodiments, when the output data substantially corresponds to one of the plurality of data signatures, the processor generates and sends an alert to a local or remote computing device. In some embodiments, the method can further determine if the output voltage remained greater or equal to the voltage threshold for at least a threshold time period.

In some embodiments, the processor communicates the alert to a remote computing device via the communication interface where the alert includes or is accompanied by the output data representative of the data signature.

In some embodiments, the data signature and voltage threshold corresponds to abnormal variations in other distribution transformer parameters, such as oil temperature, surface temperature, oil pressure, and/or current.

In some embodiments, the method further includes determining, by the processor, whether an output voltage divergence measured between a first secondary terminal and a second secondary terminal of the distribution transformer is greater than or equal to a threshold.

In some embodiments, the processor and the communication interface form part of a distribution transformer monitoring (DTM) device.

In some embodiments, the data signature and voltage threshold corresponds to a pattern where voltage magnitudes at secondary terminals of a transformer move in tandem for a period of time and then diverge substantially compared to a historical pattern.

In some embodiments, the data signature and voltage threshold corresponds to abnormal deviations in other distribution transformer parameters, including oil temperature, surface temperature, oil pressure, and/or current compared to a historical pattern. In some embodiments, the abnormal deviations are within a predetermined time period of the voltage deviation event.

In some embodiments, the method further includes validating, by the processor, whether the divergence in secondary terminal voltages is greater than or equal to a threshold value when compared to historical data and iterating a detection model when comparing to the historical data followed by sending the alert when the output voltage step indicates the failure mode in the distribution transformer.

In some embodiments, the distribution transformer is a single phase pad-mounted distribution transformer or a single phase pole-mounted transformer and where the divergence of secondary voltages is indicative of a partial primary coil failure, a loss of a neutral connection, or an irregular loading condition.

In some embodiments, the distribution transformer is a three phase pad-mounted distribution transformer or a three phase pole-mounted transformer and wherein the processor and the communication interface form part of a distribution transformer monitoring device that monitors for a divergence of loading imbalance indicative of abnormal grid or load characteristics.

In some embodiments, a distribution transformer monitoring (DTM) device includes a housing configured for attachment to a distribution transformer, a communication interface, a non-transitory memory storing processor-executable instructions, and a processor, operably coupled to the DTM device, the communication interface, and the memory. The processor is operable in accordance with the processor-executable instructions to perform the operations of monitoring output data, by the DTM device positioned on, within or proximate to a housing of the distribution transformer for detecting at least a voltage divergence event between a first secondary terminal and a second secondary terminal of the distribution transformer, determining whether output voltage data from the secondary terminals substantially corresponds to one of a plurality of data signatures representing voltage divergence events at or above a predetermined threshold, and communicating by the processor via the communication interface an alert to a local or remote computing device when the output data substantially corresponds to one of the plurality of data signatures.

In some embodiments, the processor determines whether the output data substantially corresponds to one of a plurality of data signatures by determining whether an output voltage divergence between the first secondary terminal and the second secondary terminal of the distribution transformer is greater than or equal to a first voltage threshold and determining whether the output voltage difference remained greater than or equal to the first voltage threshold for at least a threshold time period when the secondary terminal output voltages are greater or equal to a second voltage threshold.

In some embodiments, the data signature and the voltage thresholds correspond to abnormal variations in other distribution transformer parameters within a predetermined time period of the voltage divergence event, including at least one or more of oil temperature, surface temperature, oil pressure, or current.

In some embodiments, the distribution transformer is a single phase pad-mounted distribution transformer or a single phase pole-mounted transformer and the divergence of secondary voltages is indicative of a partial primary coil failure, a loss of a neutral connection, or an irregular loading condition.

### BRIEF DESCRIPTION OF THE DRAWINGS

Non-limiting and non-exhaustive embodiments are described with reference to the following drawings, wherein reference numerals refer to like components throughout the various views unless otherwise specified. The sizes and relative positions of elements in the drawings are not necessarily drawn to scale. For example, the shapes of various elements are selected, enlarged, and positioned to improve drawing legibility. The particular shapes of the elements as drawn have been selected for ease of recognition in the drawings.

FIG. 1 illustrates a block diagram of a partial electrical transmission and distribution grid in accordance with some embodiments of the present disclosure.

FIG. 2A illustrates an exemplary single-phase pad-mounted distribution transformer in accordance with some embodiments of the present disclosure.

FIG. 2B illustrates an exemplary distribution transformer monitor (DTM) having the ability to measure voltage and other parameters of a distribution transformer, in accordance with some embodiments of the present disclosure.

FIG. 3A illustrates an exemplary pad-mounted distribution transformer with a distribution transformer monitor (DTM) attached to a wall of the distribution transformer, in accordance with some embodiments of the present disclosure.

FIG. 3B illustrates the distribution transformer of FIG. 3A with a closed hatch door in accordance with some embodiments of the present disclosure.

FIG. 4 illustrates block diagram of partial electrical distribution system with a number of pad-mounted transformers having distribution transformer monitors coupled thereto for detecting secondary terminal voltages and optionally other parameters of the pad-mounted distribution transformers and wirelessly communicating data signals representative of the detected voltages to a remote computing device, in accordance with some embodiments of the present disclosure.

FIG. 5 is a block diagram of an exemplary distribution transformer monitoring system, in accordance with some embodiments of the present disclosure.

### DETAILED DESCRIPTION

In the following description, certain specific details are set forth in order to provide an understanding of various disclosed embodiments to a person of ordinary skill in the relevant art. However, one skilled in the relevant art will recognize that embodiments may be practiced without one or more of these specific details, or with other methods, components, materials, etc. Additionally, well-known structures or components may be omitted or shown and described in reduced detail to avoid unnecessarily obscuring descriptions of the embodiments.

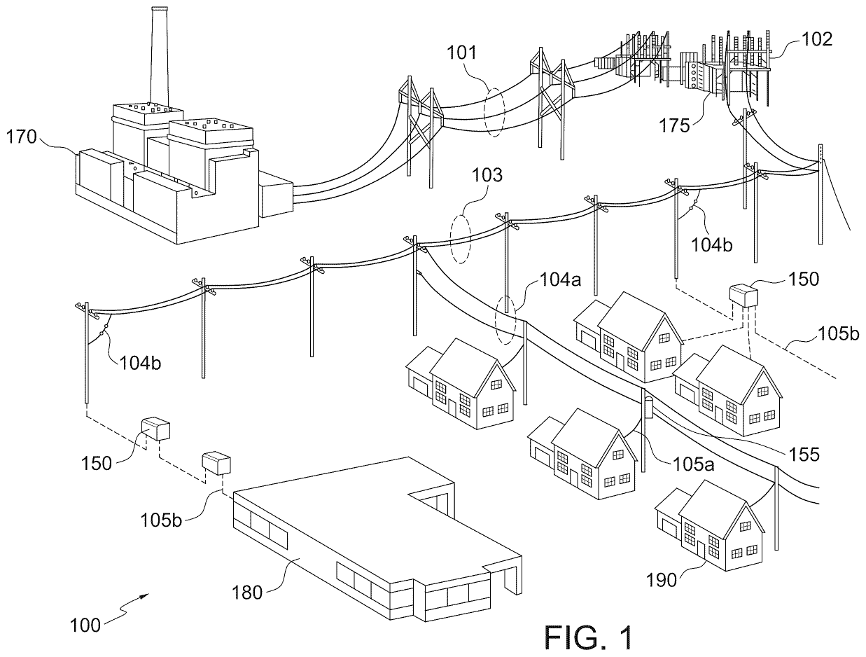

The methods, apparatus, and systems in accordance with the embodiments can form a part of an electrical power transmission and distribution system 100 or power grid as illustrated in exemplary but partial form in FIG. 1. The power transmission and distribution system 100 can include a network containing generation, distribution and transmission systems. The system 100 can use any form of energy (like coal, diesel, wind, solar, hydroelectric, etc.) and convert it into electrical energy.

A power plant 170, transmission lines 101, step-down transformers 175, substations 102, distribution lines 103, and distribution transformers 150, 155 are some of the main components of the power transmission and distribution system 100. The power plant 170 generates power, which is transferred over high voltage transmission lines 101 to step-down transformers 175 at or before substations 102.

The substations 102 deliver power to feeder distribution lines 103, which in turn pass power to lateral distribution lines 104a, 104b for delivery to distribution transformers 150, 155, which step down the voltage to an appropriate value suitable for customer use. Depending on their configuration, distribution transformers 150, 155 in the United States typically output 120V_{RMS} to 480V_{RMS} at their secondary terminals for use by utility customers, which can be commercial and industrial customers 180 or residential customers 190.

The power transmission and distribution system 100 can include high voltage transmission lines 101 from the power plant 170 to the substation 102, and distribution feeder lines 103 from the substation 102 to the eventual end users. For residential and commercial users, lateral pull offs 104a, 104b from the distribution feeder lines 103 are typically used. More particularly, overhead pull offs 104a can be used with pole mounted distribution transformers 155 and underground lateral pull offs 104b can be used with pad mounted distribution transformers 150. The pole mounted distribution transformers 155 and the pad mounted distribution transformers 150 each have high voltage primary terminals (e.g., bushings) and lower voltage secondary terminals (bushings and spades) that supply power through insulated cables to end users. In the case of pole mounted distribution transformers, an overhead secondary cable 105a can run from the pole mounted distribution transformer 155 to the residential end user 190. In the case of pad mounted distribution transformers, an underground secondary cable 105b can run from the pad mounted transformer 150 to the commercial end user 180 or residential end user 190, for example. As pictured, an underground secondary cable 105b can also run from a pad mounted transformer 150 to a residential end user 190.

The component of an electrical power system 100 connecting all the consumers in an area to the bulk power sources is called a distribution system. The bulk power stations are connected to the generating substations by transmission lines. They feed some sub-stations which are usually situated at convenient points near the load centers.

The substations distribute power to domestic, commercial and relatively small consumers. The consumers requiring large blocks of power are usually supplied at sub-transmissions or even by the transmission system.

In some embodiments, a distribution transformer monitoring device (DTM) or other device installed within a pad-mount transformer hatch, on a housing of an aerial distribution transformer 155, or otherwise proximate to a distribution transformer 150, 155 is used to detect voltages and optionally other operational parameters associated with the distribution transformer 150, 155. One embodiment can include programming an onboard processor with one or more output data signatures corresponding to voltage divergence events or other events, such as aberrant oil temperature or surface oil temperature, current, or pressure readings. An alternative embodiment can include programming a remote processor or computing device (e.g., server or cloud server instance) with output data signatures representing the particular events and sending raw output data to the remote computing device for event analysis and alarm generation. A priority schedule can also be set for various types of alarms based on the particular reading and the extent of deviations from normal readings. Other embodiments can combine the voltage data with other sensor data (such as photosensor data, oil temperature, pressure, current, etc.) to make appropriate assessments and alarms accordingly.

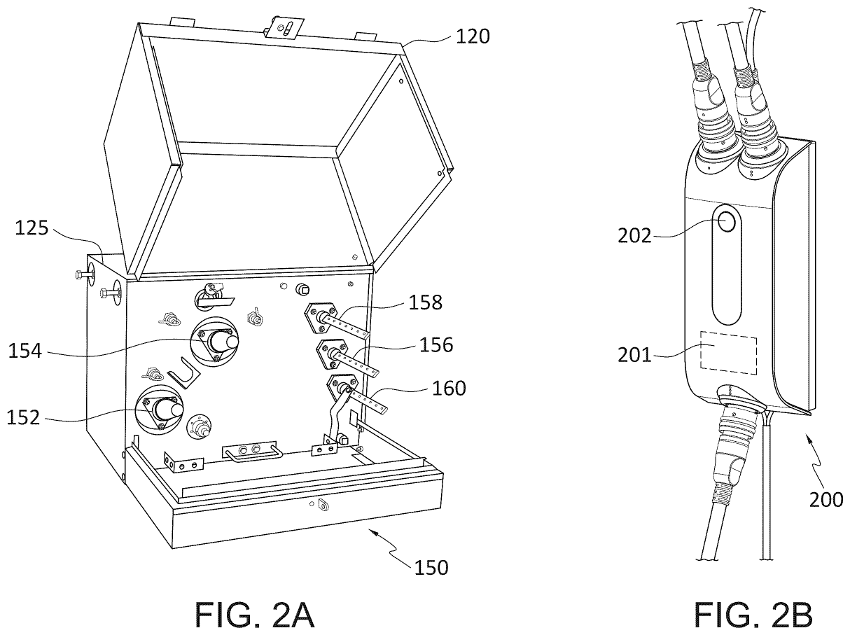

Referring to FIGS. 2A, 2B, 3A, 3B, 4, and 5, various views of an exemplary power distribution transformer 150, 155 and a distribution transformer monitor (DTM) 200 having voltage and optionally other sensors, such as an accelerometer, an optical sensor, and current sensors (e.g., Rogowski coils), implemented or used in a power distribution system are shown. More particularly, such a system can detect voltage anomalies based on signals obtained or derived from the transformer's secondary terminals to aid in predicting performance degradation of the distribution transformer 150, 155 monitored by the DTM 200. Note that the parameter sensors contemplated within the embodiments are not limited to the sensors detailed here, but can include other sensors such as cameras, current transformers, or other devices that measure current, voltage, impedance, power factor, motion, temperature, pressure, or other parameters useful in detecting potential faults or conditions requiring further review, monitoring, maintenance, repair, replacement or other desirable interventions prolonging the efficient useful life of such components and systems being monitored.

Referring to FIG. 2A, an exemplary pad-mounted distribution transformer 150 can include a high voltage primary input terminal 152, a high voltage primary output terminal 154, lower voltage secondary output terminals 156, 158, and a secondary neutral output terminal 160. Such a transformer 150 can be housed in a housing 125 having an openable and closeable hood or hatch door 120. The hatch door 120 provides easy access to the primary terminals 152, 154, the secondary terminals, 156, 158, and other components for installation and maintenance purposes. The hatch door 120 may be hinged or otherwise movably coupled to the main distribution transformer housing 125.

In some embodiments, the transformer 150 can include one or more sensors or monitors collectively referred to as a DTM 200 as shown in exemplary form in FIG. 2B, which is a specialized hardware device that collects and measures various information relating to operation of a distribution transformer 150, 155. The DTM 200 in accordance with some embodiments can also include a processor 201 and optionally other sensors 202. The embodiments herein and such DTM systems can leverage each other or in some instances be incorporated into each other. The DTM 200 may be attached onto an aerial (e.g., pole top) transformer 155 or pad-mount transformer 150 in the field or at the factory, or may be embedded within the transformer 150, 155 to create a smart transformer at the time of manufacturing. An aerial pole-mounted transformer 155 or ground-level padmount transformer 150 commonly powers anywhere from 5-8 homes (in U.S. electrical distribution systems) and is the last voltage transition in stepping down voltage before it gets to the home or business. Standard positioning of Rogowski coil and voltage sensing cables of DTM devices 200 occurs at the transformer bushings (primary or secondary, as applicable), but sometimes they are attached directly onto the secondary electricity lines. The DTM device 200 reports to a collection engine and/or existing SCADA/MDM system where relevant transformer data and other data (such as the raw motion sensor information or optical sensor information or information derived therefrom) is stored and presented to a user. Furthermore, analytics platforms may be employed to interpret the information being captured and reported by the DTM 200.

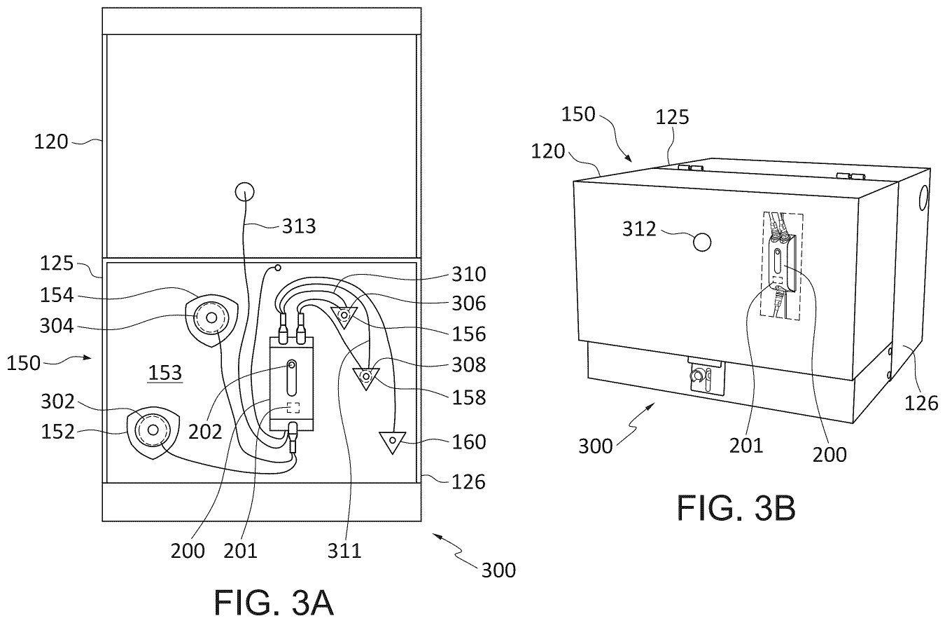

Referring to FIG. 3A, an exemplary distribution transformer monitoring system 300 includes a DTM 200 and a processor, which may be a processor 201 of the DTM 200 or a remote computing device, such as a cloud server or service 402. The monitoring system 300 may also include the monitored transformer 150, 155. As shown in FIG. 3A, the exemplary distribution transformer monitoring system 300 includes the DTM 200 of FIG. 2 and its associated cable kits, which include secondary voltage sensing cables 310, 311 and optionally, one or more other sensors, such as an optical sensor 202, Rogowski coils 302, 304 for sensing input and output currents primary terminal, and Rogowski coils 306, 308 for sensing secondary terminal currents. When used, the primary terminal Rogowski coils 302, 304 are positioned to encircle the respective primary input and output terminals 152, 154 (e.g., primary bushings) of the transformer 150, 155. Similarly, when used, the secondary terminal Rogowski coils 306, 308 are positioned to encircle respective secondary output terminals 156, 158 (e.g., secondary bushings or spades) of the transformer 150, 155. The monitoring system may communicate sensed data to a remote computing device. Accordingly, the monitoring system 300 and/or the DTM 200 may include a wireless transceiver that communicates wireless signals to an antenna cable 313 for transmission by an antenna 312. As illustrated in FIGS. 3A and 3B, the antenna 312 and the antenna cable 313 may be external to the DTM 200 for padmount transformer installations. On the other hand, the antenna 312 may be internal to the DTM 200 for pole-mounted or aerial transformer installations, thereby eliminating the need for the external antenna cable 313. As further illustrated in FIG. 3B, the hatch door 120 of the padmount distribution transformer 150 is closed against the sealed tank portion 126 of the main housing 125 of the transformer 150 to prevent unauthorized access to the primary and secondary terminals of the transformer 150.

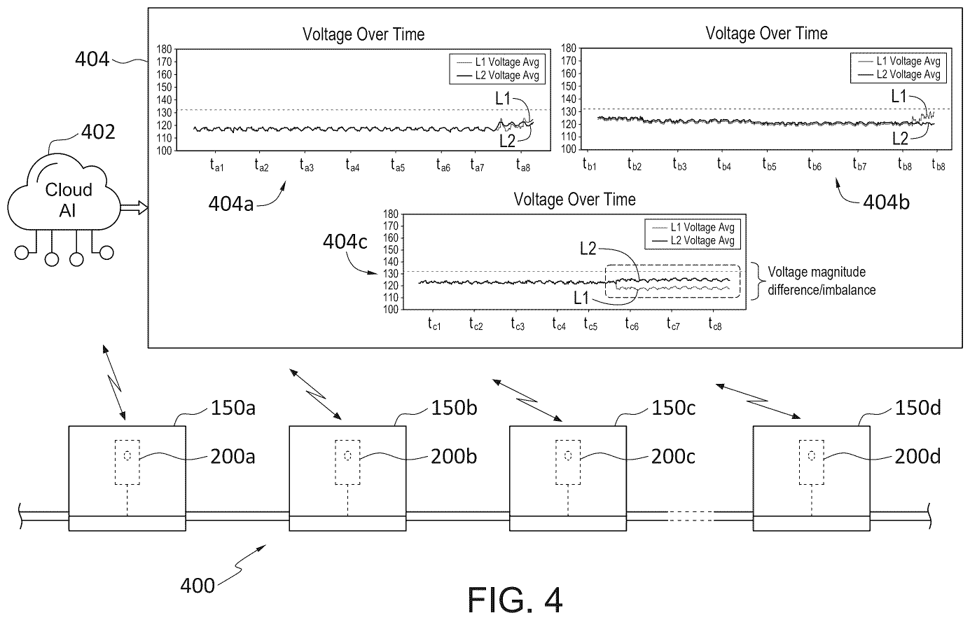

FIG. 4 illustrates block diagram of partial electrical distribution system 400 with a number of pad-mounted transformers 150a-150d having distribution transformer monitors 200a-200d coupled thereto for detecting secondary terminal voltages and optionally other parameters of the pad-mounted distribution transformers 150a-150d and wirelessly communicating data signals representative of the detected voltages to a remote computing device 402, in accordance with some embodiments of the present disclosure. As illustrated in FIG. 4, the DTMs 200a-200d may present real-time and/or historical information about a respective transformer 150a-150d, upon or at which it is installed, in addition to creating a vital ongoing information access point within a grid architecture. The DTMs 200a-200d can use wireless transceivers (modems) to transmit data signals representative of sensed voltages or other operating parameters to a remote computing device 402, such as a cloud server or server instance, for performance of data analytics with respect to the DTMs 200a-200d and the grid.

According to some of the embodiments of the present disclosure, artificial intelligence (AI) machine learning (ML) models or programs are executed within the remote computing device 402 to predict distribution transformer degradation based on secondary voltage divergence as determined from voltage data signals communicated from the DTMs 200a-200d. In some embodiments, an AI fault detection analysis engine executing the AI/ML models on the remote computing device 402 (or within one or more of the DTM processors) performs analysis using event triggers, scheduled reporting, or polling techniques to monitor secondary terminal and/or primary terminal voltages over time (e.g., voltage waveform data), which can be displayed on a dashboard 404 of a web application accessible through an Internet-connected computer logged into the remote computing device 402. Additional data supplied by the DTMs 200a-200d from Rogowski coils and other sensors can further help classify or categorize types of distribution transformer or other grid faults that are detected and provide a better fault location vector to pinpoint the locations of such faults on a more granular level. Calculations and/or measurements can be done for some or each transformer in the distribution system 400. Sensor data collected by the DTMs 200a-200d is transmitted to the remote computing device 402 preferably via a wireless connection but may be alternatively communicated over a wired link. In some embodiments, secondary voltage divergence can be detected between a first secondary terminal 156 and a second secondary terminal 158 of a distribution transformer 150a-150d. Such secondary divergence may be indicative of transformer performance degradation, especially where other distribution transformers in the same geographic area are not also exhibiting such behavior, which could indicate an anomaly in the primary voltage.

According to some embodiments, a potential failure pattern or signature for a distribution transformer 150, 155 includes secondary voltage divergence, especially when such divergence remains consistent of a threshold period of time. For example, secondary terminal voltage magnitudes in healthy distribution transformers are generally balanced and consistent, moving in tandem with one another under normal operation as generally shown in voltage magnitude waveform or series graph 404a, where L1 identifies the waveform for voltage magnitudes detected at one secondary terminal 156 over time and L2 identifies the waveform for voltage magnitudes detected at another secondary terminal 158 over time. As illustrated in voltage magnitude waveform graph 404b, the voltage magnitudes at the secondary terminals 156, 158 may begin to diverge over time potentially indicating a performance issue with the transformer 150. Performance degradation of the transformer 150, 155 can be confirmed through detection of longer lasting or more permanent voltage magnitude differences or imbalance between the secondary terminals 156, 158 as shown in voltage magnitude waveform graph 404c, indicating a transformer performance degradation needing action. For example, when the voltage magnitude divergence remains for a threshold period of time, such as at least 12 hours or at least 24 hours, the transformer 150, 155 is likely in a failure mode. The waveforms shown in voltage magnitude waveform graphs 404b, 404c provide exemplary signatures indicating potential transformer performance degradation. Flagging or alerting as to these events enables utility personnel to take early action to investigate, repair, or replace a transformer 150, 155 before a major transformer failure occurs.

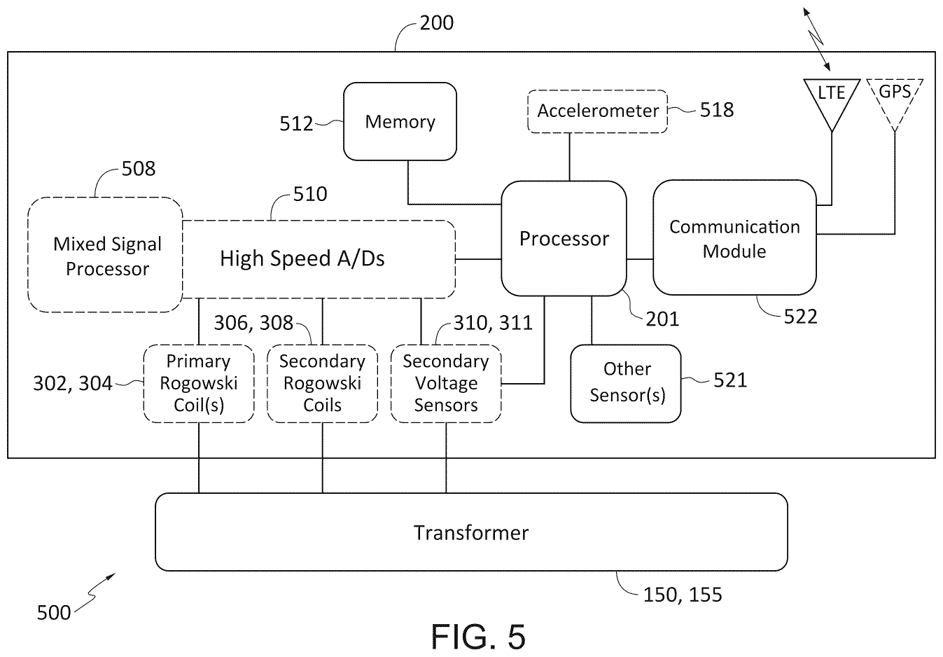

An exemplary DTM 200, as illustrated in block diagram form in the exemplary distribution transformer monitoring system 500 of FIG. 5, may include a number of separate components or components that form part of a number of integrated devices that include all or some of the functionality of the separate individual components. For example, the exemplary DTM 200 includes, inter alia, secondary Rogowski coils 306, 308 (where the DTM 200 monitors current delivered from the secondary terminals 156, 158 of the transformer 150), secondary voltage sensing cables 310, 311 supplying secondary voltages to voltage sensing circuits within the DTM 200, and other sensor(s) 521 (which may include an optical sensor 202), a processor 201, a communication module 522, non-transitory memory 512, and a wireless communication antenna (e.g., an LTE or 5G antenna). The DTM 200 may also include a further optional Rogowski coil system, which can include one or more primary Rogowski coils 302, 304 in addition to the one or more secondary Rogowski coils 306, 308 (which may also include voltage sensing for divergence purposes), and one or more high-speed analog-to-digital converters (ADCs) 510. The DTM 200 may further include an accelerometer 518 (such as a G-sensor), a global positioning system (GPS) antenna, and associated receiver and processing circuitry. The memory 512 stores instructions (e.g., software, firmware, machine code, object code, etc.) executable by the processor 201 to perform various computing and control operations as described herein.

In yet another embodiment, the DTM 200 may optionally include a mixed signal processor 508 designed for high accuracy measurement of power and energy in power line systems using Rogowski coils, current transformers, or shunt current sensors. When included, such a processor 508 can provide instantaneous voltage and current waveform data and calculate RMS values of voltages and currents, as well as active, reactive, and apparent power and energy.

The DTM processor 201 can communicate voltage magnitude and other data received from the ADCs 510 to a communication module 522 (e.g., an LTE or 5G modem) which supports communication via LTE, 5G, or other communication protocols and may also be able to receive and transmit GPS or other location data to a remote processor or server 402. The output of each secondary voltage sensor is sampled by the high speed ADCs 510 with the ADC digital outputs supplied to the DTM processor 201 for adding as payload to communication packets provided to the communication module 522.

In some embodiments, the communication module 522 can include a global positioning system receiver and in other embodiments a separate GPS receiver can be coupled to at least one or more transformers among the plurality of transformers to detect any sudden movement or acceleration (earthquake, tremor, crash impact, lightning strike, projectile impact, bullet or other artillery impact, etc.). In some embodiments, the system can further monitor and transmit data representative of a voltage or current waveform for at least one or more of the transformers in such a system using the parameter sensors or Rogowski coil or coils (and a waveform capturing and processing device or display) as previously described. The system would generally be configured to generate an alert when at least the corresponding waveform (or certain data) is beyond a predetermined deviation from a reference waveform (or from reference data).

In some embodiments, a method for detecting a voltage divergence event within or proximate a distribution transformer 150, 155 can include generating output data (by a Rogowski coil or other voltage meter) and determining, by a processor (e.g., remote computing device 402 or onboard processor 201) receiving the data, whether the output data substantially matches one of a plurality of output data signatures representing corresponding event signatures. The method can further include when the output data substantially matches one of the output data signatures, generating and communicating, by the processor via a communication interface, an alert to a remote computing device. The method then continues to monitor. If the method fails to find a matching signature, the method again continues to monitor.

The output data signature in this instance would be an automated fault detection system for a pattern of Line 1 (X1 terminal 156), Line 2 (X3 terminal 158) secondary voltage relationship breakdown. The pattern to recognize is a change from having the two lines move in tandem to at least one line not following the regular pattern and diverging substantially. Referring to FIG. 4, one example in a dashboard 404 displayed by the cloud server 402 shows a voltage time series graph 404a for a distribution transformer 150 with X1, X3 terminal voltage magnitude relationship deterioration prior to failure. Voltage time series graph 404b provides another example of a more pronounced voltage magnitude relationship deterioration. Voltage time series graph 404c is yet another example where a significant change in relationship between secondary terminals 156, 158 compared with historical data indicative of potential transformer failure (with the voltage magnitude difference at the secondary terminals 156, 158 remaining above the threshold for a minimum period of time, such as 24 hours).

In some embodiments, determination of whether the secondary voltage magnitude data substantially matches one of a plurality of data signatures representing corresponding event signatures can be performed according to a method executed by the. In such a case, the processor 402 determines whether an output voltage magnitude divergence or imbalance is greater than a voltage threshold and optionally further determining by the processor when the output voltage is greater than the voltage threshold whether the output voltage imbalance remained greater than the threshold for at least a minimum time period which is representative of one of the plurality of output data signatures. The method can further determine whether the sensor output voltage or signal signature substantially corresponds to one of a plurality of signal signatures, and further (generating and) communicating by the processor via the communication interface (e.g., an Internet-accessible dashboard 404), the alert to a user (e.g., the utility operating the electric power distribution system that includes the distribution transformer 150) with information representative of one of the plurality of output data signatures. If the output voltage magnitude difference from the secondary terminals 156, 158 is not greater than the voltage magnitude threshold, the method continues to monitor. If the output voltage magnitude difference or imbalance fails to remain greater than the voltage threshold for at least a minimum time period, the method also proceeds to continue monitoring. If the output voltage fails to correspond to one of the plurality of signal signatures, the method also proceeds to continue monitoring.

In some embodiments, a method for detecting at least a voltage divergence event associated with (e.g., within or proximate to) a distribution transformer such as a pad-mounted or aerial distribution transformer or pole-mounted transformer may include monitoring output data or one or more output signals (such as one or more voltage or current signals or other distribution transformer parameters) and determining, by a processor operably coupled to the distribution transformer, whether the output data or output signal(s) substantially corresponds to one or more data signatures representing voltage divergence events or other events at or above a predetermined threshold indicative of a potential failure mode of the distribution transformer. The method may further include communicating, by the processor via a communication interface, an alert to a local or a remote computing device when the output data or output signal(s) substantially corresponds to one of the data signatures.

In some embodiments, the method can determine whether the output data substantially corresponds to one of a plurality of data signatures by determining, by the processor, whether an output voltage divergence measured from secondary voltage outputs of the distribution transformer (or transformers) is greater than or equal to a voltage threshold. When the output voltage is greater or equal to the voltage threshold, the processor determines whether the output voltage remained greater than or equal to the voltage threshold for at least a threshold time period.

In some embodiments, the method communicates the alert to a remote computing device via the communication interface where the alert includes or is accompanied by the output data representative of the data signature. In some embodiments the data signature and voltage threshold corresponds to abnormal variations in other distribution transformer parameters. In some embodiments, the data signature and voltage threshold corresponds to abnormal variations in other distribution transformer parameters including at least one or more of oil temperature, surface temperature, oil pressure, or current. In some embodiments the data signature and voltage threshold corresponds to abnormal variations in other distribution transformer parameters including oil temperature, surface temperature, oil pressure, and current.

In some embodiments, the data signature and voltage threshold corresponds to abnormal variations in other distribution transformer parameters within a predetermined time period of the voltage deviation event, including at least one or more of oil temperature, surface temperature, oil pressure, or current.

In some embodiments, the method can include attaching transformer monitoring sensors to multiple transformers in a given neighborhood, communicating secondary voltage, current, temperature and/or pressure data back to a backend cloud database, analyzing such data to look for the correlation between secondary voltage lines being lost and the relationship changing from what it was historically. The system can report such aberrant behavior to the utility's maintenance and operations team to proactively maintain the health of the various individual transformers and corresponding electronic grid.

In some embodiments, the distribution transformer is a pad-mounted distribution transformer or a pole-mounted transformer. In some embodiments, the distribution transformer is a pad-mounted distribution transformer or a pole-mounted transformer and the processor and the communication interface form part of a distribution transformer monitoring device.

In some embodiments, a distribution transformer monitoring system 300, 500, as shown in FIG. 3 or FIG. 5, includes a DTM 200 positioned on, within or proximate to a distribution transformer 150, 155, a communication module 522, a non-transitory memory 512 storing processor-executable instructions, a processor 201, a communication module 522, and a memory 512. The processor 201 may be operably coupled to high speed ADCs 510 (which may be separate from or form part of a mixed signal processor 508). The processor 201 or a remote processing device 402 is operable in accordance with the processor-executable instructions to perform the operations of monitoring output data, by the DTM device 200, for detecting at least a voltage divergence or imbalance event associated with the distribution transformer 150, 155, determining whether the output data substantially corresponds to one of a plurality of data signatures representing voltage divergence events at or above a predetermined threshold, and communicating an alert (e.g., via email, text, or a notification on an Internet-accessible dashboard 404) when the output data substantially corresponds to one of the plurality of data signatures.

In some embodiments, the processor 201 or remote computing device 402 determines whether the output data substantially corresponds to one of a plurality of data signatures by determining whether output voltages measured from the secondary output terminals 156, 158 of the distribution transformer 150, 155 (using secondary voltage sensing cables 310, 311 and associated voltage sensing circuits, for example) have a divergence greater than or equal to a voltage threshold and, if so, whether the voltage divergence remained greater than or equal to the divergence threshold for at least a threshold time period.

In some embodiments, the data signature and voltage threshold may correspond to abnormal variations in other distribution transformer parameters within a predetermined time period of the voltage deviation event, including at least one or more of oil temperature, surface temperature, oil pressure, or current.

In some embodiments, as shown in FIG. 5, a distribution transformer monitoring system 300, 500 includes a DTM device 200 on, within or proximate to a housing of a distribution transformer 150, 155, a communication module 522, a non-transitory memory 512 storing processor-executable instructions, and a processor 201, operably coupled to the DTM device 200, the communication module 522, and the memory 512. In some embodiments, the processor 201 operates in accordance with processor-executable instructions to perform operations of: monitoring secondary output voltage data of the distribution transformer 150, 155 for detecting at least a voltage divergence event associated with the distribution transformer 150, 155, determining whether a difference between magnitudes of voltages at secondary output terminals 156, 158 of the distribution transformer 150, 155 is greater than or equal to a voltage threshold, determining whether the output voltage difference or divergence remained greater than or equal to the voltage threshold for at least a threshold time period, and, if so, determining that performance of the distribution transformer 150, 155 has degraded or is likely degrading. In some embodiments, the processor 201 communicates via the communication module 522 an alert to a local or remote computing device 402.

In some embodiments, the data signature and voltage threshold correspond to or coincide with abnormal variations in other distribution transformer parameters within a predetermined time period of the voltage divergence event, including at least one or more of oil temperature, surface temperature, oil pressure, or current.

According to one or more embodiments of the present disclosure, a processor executes a method for predicting performance degradation of a distribution transformer 150, 155 in an electrical power distribution system. The processor may be a cloud server 402 located remotely from the distribution transformer 150, 155 (e.g., in a cloud environment) or a processor 201 in a DTM 200 collocated with the distribution transformer 150, 155 (e.g., positioned on, within, or proximate to the distribution transformer 150, 155). According to one exemplary embodiment, the processor 402 receives data signals representative of voltages at two or more secondary terminals 156, 158 of the distribution transformer 150, 155 (e.g., two secondary terminals of a single-phase distribution transformer 150, 155). The data signals may be generated by the DTM processor 201 from the outputs of high speed analog-to-digital converters 510 operating on the secondary terminal voltages detected or sensed through voltage sensing cables 310, 311 by secondary terminal voltage sensing circuits. Where the processor 402 is located remotely from the DTM 200, the DTM processor 201 may communicate the generated data signals through a communication module 522, such as an LTE, 5G, or other wireless, wired, fiber optic, cable, Ethernet, or other modem depending on the communication path between the DTM 200 and the processor 402.

The processor 402 determines, from the received data signals, a difference between the magnitudes of the voltages at two secondary terminals 156, 158 to produce a voltage magnitude difference. The processor 402 then determines whether the voltage magnitude difference (peak or RMS) is greater than a threshold and, when it is, further determines that the performance of the distribution transformer 150, 155 has degraded or is degrading. To mitigate the likelihood of false positives (e.g., due to varying loading on the secondary terminals 156, 158 or otherwise), the processor 402 may continue to monitor the secondary terminal voltages and determine the voltage magnitude difference over a minimum period of time, such as 12 hours, 24 hours, etc., to confirm that transformer performance degradation has occurred or is in process.

According to one exemplary embodiment, the voltage difference threshold may be set to about 3% of the magnitude of the secondary terminal output voltage (e.g., about 3.6 V_{RMS} where the nominal output voltage of each secondary terminal 156, 158 is typically about 120 V_{RMS}). According to alternative embodiments, the voltage difference threshold may be set to any value in a range of about 2% to about 5% of the nominal magnitude of the voltage at either secondary terminal 156, 158. Therefore, where the nominal output voltage of each secondary terminal 156, 158 is typically about 120V_{RMS}, the voltage difference threshold may be set to any value in a range of about 2.5 V_{RMS} to about 5.0 V_{RMS}.

After determining that distribution transformer performance has degraded or is degrading, the processor 402 may communicate a notification to a utility owning or controlling the distribution transformer 150, 155 to inform that the performance of the distribution transformer 150, 155 has degraded or is degrading. Such notification may be communicated by email, text, or other conventional means, or may more preferably be communicated by adding an alert to an Internet-accessible dashboard 404 used by the utility to manage infrastructure components of the utility's electrical distribution system.

According to another exemplary embodiment of the present disclosure, a distribution transformer monitoring system 300, 500 includes a monitoring device 200 and a processor 402. According to this embodiment, the monitoring device 200 is collocated with a distribution transformer 150, 155 and configured to (i) detect voltages at two or more secondary terminals 156, 158 of the distribution transformer 150, 155 and (ii) generate data signals representative of the detected voltages. Additionally, the processor 402 is operable in accordance with stored operating instructions (e.g., stored in non-transitory memory) to: receive the data signals from the monitoring device 200; determine from the received data signals, a difference between magnitudes (either peak or, more preferably, RMS) of voltages at two of the distribution transformer's secondary terminals 156, 158 to produce a voltage magnitude difference; determine whether the voltage magnitude difference is greater than a threshold (either instantaneously or, more preferably, for at least a minimum period of time); and determine that performance of the distribution transformer 150, 155 has degraded or is degrading when the voltage magnitude difference is greater than the threshold. Where RMS voltages are used to determine the voltage magnitude difference or imbalance, the data signals generated by the monitoring device 200 and received by the processor 402 are representative of the RMS voltages at the two secondary terminals 156, 158 of the distribution transformer 150, 155. All details disclosed above and related to the operation of the processor 402, the monitoring device 200 (e.g., DTM), and all of the components thereof apply to their use in the distribution transformer monitoring system of this embodiment.

According to a further exemplary embodiment of the present disclosure, a distribution transformer monitoring system 300, 500 includes a distribution transformer 150, 155, a monitoring device 200, and a processor 402. According to this embodiment, the monitoring device 200 is collocated with the distribution transformer 150, 155 and configured to (i) detect voltages at two or more secondary terminals 156, 158 of the distribution transformer 150, 155 and (ii) generate data signals representative of the detected voltages. Additionally, the processor 402 is operable in accordance with stored operating instructions (e.g., stored in non-transitory memory) to: receive the data signals from the monitoring device 200; determine from the received data signals a difference between magnitudes of voltages at two of the distribution transformer's secondary terminals 156, 158 to produce a voltage magnitude difference; determine whether the voltage magnitude difference is greater than a threshold (either instantaneously or, more preferably, for at least a minimum period of time); and determine that performance of the distribution transformer 150 has degraded or is degrading when the voltage magnitude difference is greater than the threshold. Where RMS voltages are used to determine the voltage magnitude difference or imbalance, the data signals generated by the monitoring device 200 and received by the processor 402 are representative of the RMS voltages at the two secondary terminals 156, 158 of the distribution transformer 150, 155. All details disclosed above and related to the operation of the processor 402, the monitoring device 200, and all of the components thereof apply to their use in the distribution transformer monitoring system 300, 500 of this embodiment.

In the absence of any specific clarification related to its express use in a particular context, where the terms “substantial,” “approximately,” or “about” in any grammatical form are used as modifiers in the present disclosure and any appended claims (e.g., to modify a structure, a dimension, a measurement, or some other characteristic), it is understood that the characteristic may vary by up to 30 percent.

The terms “include” and “comprise” as well as derivatives thereof, in all of their syntactic contexts, are to be construed without limitation in an open, inclusive sense, (e.g., “including, but not limited to”). The term “or,” is inclusive, meaning “and/or.” The phrases “associated with” and “associated therewith,” as well as derivatives thereof, can be understood as meaning to include, be included within, interconnect with, contain, be contained within, connect to or with, couple to or with, be communicable with, cooperate with, interleave, juxtapose, be proximate to, be bound to or with, have, have a property of, or the like.

Reference throughout this specification to “one embodiment” or “an embodiment” or “some embodiments” and variations thereof mean that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. The various embodiments described above can also be combined to provide further embodiments.

As used in this specification and the appended claims, the singular forms “a,” “an,” and “the” include plural referents unless the content and context clearly dictates otherwise. Additionally, conjunctive and disjunctive terms, “and” and “or,” are generally employed in the broadest sense to include “and/or” unless the content and context clearly dictates inclusivity or exclusivity as the case may be. In addition, the composition of “and” and “or” when recited herein as “and/or” is intended to encompass an embodiment that includes all of the associated items and one or more other alternative embodiments that include fewer than all of the associated items.

What is claimed is:

1. A method for predicting performance degradation of a distribution transformer in an electrical power distribution system, the method comprising:
receiving, at a processor, data signals representative of voltages at two or more secondary terminals of the distribution transformer;
determining, by the processor from the received data signals, a difference between a magnitude of a voltage at a first secondary terminal of the two or more secondary terminals and a magnitude of a voltage at a second secondary terminal of the two or more secondary terminals to produce a voltage magnitude difference;
determining, by the processor, whether the voltage magnitude difference is greater than a threshold; and
determining, by the processor, that performance of the distribution transformer has degraded or is degrading when the voltage magnitude difference is greater than the threshold.

2. The method of claim 1, wherein the data signals are representative of root mean square (RMS) voltages at the two or more secondary terminals of the distribution transformer.

3. The method of claim 1, further comprising:
communicating, by the processor, a notification to a utility to inform that the performance of the distribution transformer has degraded or is degrading.

4. The method of claim 3, wherein communicating the notification to the utility comprises:
adding an alert to an Internet-accessible dashboard used by the utility to manage infrastructure components of the electrical distribution system.

5. The method of claim 1, further comprising:
detecting, by a monitoring device, the voltages at the two or more secondary terminals of the distribution transformer; and
communicating, by the monitoring device, the data signals to the processor, wherein the processor is located remotely from the monitoring device and the distribution transformer.

6. The method of claim 5, wherein the monitoring device is positioned on, within, or proximate to the distribution transformer.

7. The method of claim 1, wherein the step of receiving the data signals comprises:
receiving the data signals from a monitoring device configured to detect the voltages at the two or more secondary terminals of the distribution transformer, wherein the processor is located remotely from the monitoring device and the distribution transformer.

8. The method of claim 1, wherein the step of determining that performance of the distribution transformer has degraded or is degrading comprises:
determining that the voltage magnitude difference is greater than the threshold for at least a minimum period of time.

9. The method of claim 8, wherein the minimum period of time is twenty-four hours.

10. The method of claim 1, wherein the threshold is in a range of about 2% to about 5% of either the magnitude of the voltage at the first secondary terminal or the magnitude of the voltage at the second secondary terminal.

11. The method of claim 10, wherein the magnitude of the voltage at the first secondary terminal is nominally 120 V_{RMS}, the magnitude of the voltage at the second secondary terminal is nominally 120 V_{RMS}, and the threshold is in a range of about 2.5 V_{RMS} to about 5.0 V_{RMS}.

12. The method of claim 1, wherein the data signals are communicated from a monitoring device collocated with the distribution transformer, the monitoring device monitoring at least the voltages at the two or more secondary terminals of the distribution transformer.

13. The method of claim 1, wherein the processor is located remotely from the distribution transformer and resides in a cloud environment.

14. The method of claim 1, wherein the processor forms part of a monitoring device collocated with the distribution transformer.

15. A distribution transformer monitoring system comprising:
a monitoring device collocated with a distribution transformer, the monitoring device being configured to detect voltages at two or more secondary terminals of the distribution transformer and generate data signals representative of the detected secondary terminal voltages; and
a processor operable in accordance with stored operating instructions to:
receive the data signals;
determine, from the received data signals, a difference between a magnitude of a voltage at a first secondary terminal of the two or more secondary terminals and a magnitude of a voltage at a second secondary terminal of the two or more secondary terminals to produce a voltage magnitude difference;
determine whether the voltage magnitude difference is greater than a threshold; and
determine that performance of the distribution transformer has degraded or is degrading when the voltage magnitude difference is greater than the threshold.

16. The distribution transformer monitoring system of claim 15, wherein the processor is located remotely from the monitoring device and wherein the monitoring device is further configured to wirelessly communicate the data signals to the processor.

17. The distribution transformer monitoring system of claim 15, wherein the threshold is in a range of about 2% to about 5% of either the magnitude of the voltage at the first secondary terminal or the magnitude of the voltage at the second secondary terminal.

18. The distribution transformer monitoring system of claim 15, further comprising:
the distribution transformer.

19. A distribution transformer monitoring system comprising:
a monitoring device collocated with a distribution transformer, the monitoring device being configured to detect voltages at two or more secondary terminals of the distribution transformer and generate data signals representative of the detected secondary terminal voltages; and
a processor operable in accordance with stored operating instructions to:
receive the data signals;
determine, from the received data signals, a difference between a magnitude of a voltage at a first secondary terminal of the two or more secondary terminals and a magnitude of a voltage at a second secondary terminal of the two or more secondary terminals to produce a voltage magnitude difference;
determine whether the voltage magnitude difference is greater than a threshold for at least a minimum period of time; and
determine that performance of the distribution transformer has degraded or is degrading when the voltage magnitude difference is greater than the threshold for at least the minimum period of time.

20. The distribution transformer monitoring system of claim 19, wherein the minimum period of time is twenty-four hours.
